(19) United States
(12) Patent Application Publication
(10) Pub. No.: US 2020/0135630 A1
(43) Pub. Date: Apr. 30, 2020

(54) INTERCONNECT SUBSTRATE WITH ETCHING STOPPERS WITHIN CAVITY AND METAL LEADS AROUND CAVITY AND SEMICONDUCTOR ASSEMBLY USING THE SAME

(71) Applicant: BRIDGE SEMICONDUCTOR CORP., Taipei City (TW)

(72) Inventors: Charles W. C. LIN, Singapore (SG); Chia-Chung WANG, Hsinchu County (TW)

(21) Appl. No.: 16/730,814

(22) Filed: Dec. 30, 2019

Related U.S. Application Data
(63) Continuation-in-part of application No. 15/872,828, filed on Jan. 16, 2018, now Pat. No. 10,546,808.
Application No. 15/872,828 is a continuation-in-part of application No. 15/642,253, filed on Jul. 5, 2017.
Application No. 15/642,253 is a continuation-in-part of application No. 15/642,256, filed on Jul. 5, 2017, now abandoned.
Application No. 15/642,256 is a continuation-in-part of application No. 15/787,366, filed on Oct. 18, 2017, now Pat. No. 10,199,321.
Application No. 15/787,366 is a continuation-in-part of application No. 15/863,998, filed on Jan. 8, 2018.
Application No. 15/642,253 is a continuation-in-part of application No. 14/621,332, filed on Feb. 12, 2015, now abandoned.
Application No. 14/621,332 is a continuation-in-part of application No. 14/846,987, filed on Sep. 7, 2015, now Pat. No. 10,420,204.
Application No. 15/787,366 is a continuation-in-part of application No. 15/247,443, filed on Aug. 25, 2016, now Pat. No. 9,825,009.
Application No. 15/863,998 is a continuation-in-part of application No. 14/621,332, filed on Feb. 12, 2015, now abandoned.
Application No. 14/621,332 is a continuation-in-part of application No. 14/846,987, filed on Sep. 7, 2015, now Pat. No. 10,420,204.
Application No. 14/846,987 is a continuation-in-part of application No. 15/642,253, filed on Jul. 5, 2017.
Application No. 15/642,253 is a continuation-in-part of application No. 15/642,256, filed on Jul. 5, 2017, now abandoned.
Application No. 15/247,443 is a continuation-in-part of application No. 14/621,332, filed on Feb. 12, 2015, now abandoned.
(60) Provisional application No. 61/949,652, filed on Mar. 7, 2014.
(60) Provisional application No. 62/214,187, filed on Sep. 3, 2015.

(51) Int. Cl. H01L 23/498; H01L 23/31; H01L 23/00

(52) U.S. Cl. CPC H01L 23/49833; H01L 24/13; H01L 23/3121; H01L 23/49861

(57) ABSTRACT

The interconnect substrate includes etching stoppers within a cavity and a plurality of metal leads disposed around the cavity. The cavity is formed by etching a sacrificial metal slug of a leadframe and laterally surrounded by a resin compound. The etching stoppers are deposited in pits of the metal slug and contact a routing circuitry. By removal of the metal slug, the etching stoppers are exposed from the cavity to provide electrical contacts for device connection within cavity. Due to high etch resistance of the etching stoppers, the integrity of the electrical contacts can be ensured during the cavity formation. As a result, a semiconductor device can be face-down disposed in the cavity and electrically connected to the reliable electrical contacts at the floor of the cavity.

### CROSS REFERENCE TO RELATED APPLICATIONS

This application is a continuation-in-part of U.S. application Ser. No. 15/872,828 filed Jan. 16, 2018. The U.S. application Ser. No. 15/872,828 is a continuation-in-part of U.S. application Ser. No. 15/642,253 filed Jul. 5, 2017, a continuation-in-part of U.S. application Ser. No. 15/642,256 filed Jul. 5, 2017, a continuation-in-part of U.S. application Ser. No. 15/787,366 filed Oct. 18, 2017 and a continuation-in-part of U.S. application Ser. No. 15/863,998 filed Jan. 8, 2018.

The U.S. application Ser. No. 15/642,253 is a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 15/787,366 is a continuation-in-part of U.S. application Ser. No. 15/247,443 filed Aug. 25, 2016. The U.S. application Ser. No. 15/863,998 is a continuation-in-part of U.S. application Ser. No. 14/621,332 filed Feb. 12, 2015, a continuation-in-part of U.S. application Ser. No. 14/846,987 filed Sep. 7, 2015, a continuation-in-part of U.S. application Ser. No. 15/642,253 filed Jul. 5, 2017 and a continuation-in-part of U.S. application Ser. No. 15/642,256 filed Jul. 5, 2017.

The U.S. application Ser. No. 14/621,332 claims the benefit of filing date of U.S. Provisional Application Ser. No. 61/949,652 filed Mar. 7, 2014. The U.S. application Ser. No. 14/846,987 is a continuation-in-part of U.S. application Ser. No. 14/621,332 filed Feb. 12, 2015. The U.S. application Ser. No. 15/247,443 claims the benefit of filing date of U.S. Provisional Application Ser. No. 62/214,187 filed Sep. 3, 2015. The entirety of each of said Applications is incorporated herein by reference.

### FIELD OF THE INVENTION

The present invention relates to an interconnect substrate and a stackable semiconductor assembly using the same and, more particularly, to an interconnect substrate having etching stoppers within a cavity and metal leads around the cavity, and a stackable semiconductor assembly using the interconnect substrate.

### DESCRIPTION OF RELATED ART

Market trends of multimedia devices demand for faster and slimmer designs. One of the approaches is to assemble multiple devices on an interconnect substrate with stacking configuration so that the electrical performance can be improved and the form-factor can be further minimized. U.S. Pat. No. 7,894,203 discloses an interconnect substrate having a cavity for such kind of purpose. The disclosed substrate is made of two separated parts bonded together by an adhesive. The electrical connection between them is through a conductive material such as solder or conductive bump. As the substrate is a stacked structure, warpage or thermal expansion coefficient (CTE) mismatches between these two parts will result in dislocation or solder cracking, making this kind of stacking structure unreliable for practical usage. Alternatively, as described in U.S. Pat. No. 7,989,950, vertical connection channel is formed by attaching a solder ball on a substrate and sealed by encapsulation and thus form a cavity. Again, solder deforming and cracking in the encapsulation, or delamination between the encapsulant and the substrate after thermal cycling may lead to abrupt device failure and I/O disconnection.

For the reasons stated above, and for other reasons stated below, developing an interconnect substrate having electrical contacts disposed at the bottom of a cavity and having integral metal leads extending to the top and bottom of the wiring substrate for an ultra-thin 3D stacking of semiconductor assembly would be highly desirable.

### SUMMARY OF THE INVENTION

An objective of the present invention is to provide an interconnect substrate having a cavity through depleting a metal slug. As the metal slug is surrounded by a resin compound, thereby allowing a device disposed in the well-defined cavity without contributing much thickness to the final assembly.

Another objective of the present invention is to provide an interconnect substrate having metal leads as vertical stacking channels embedded in the resin that surrounds the cavity. As a result, a device disposed in the cavity can be stacked with another device through the metal leads without the need for other external interconnection.

Yet another objective of the present invention is to provide an interconnect substrate having electrical contacts at the floor of the cavity, thereby allowing a device disposed in the cavity can contact the substrate directly from the bottom of the cavity without contributing much thickness to the final assembly. The integrity of the electrical contacts is ensured by electroplating of an array of etching stoppers on the metal slug before its removal without extra processing steps for cost saving, yield improving and better assembly reliability.

In accordance with the foregoing and other objectives, the present invention provides an interconnect substrate, comprising: a plurality of metal leads that laterally surround a predetermined area and each have a top end and a bottom end; a resin compound that fills in spaces between the metal leads and laterally extends into the predetermined area to laterally surround a periphery of cavity at the predetermined area and has a top surface adjacent to an entrance of the cavity; a dielectric layer that covers a floor of the cavity and has a bottom surface positioned at a level below the floor of the cavity; a plurality of through openings that are aligned with the cavity and disposed in the dielectric layer; a routing circuitry that laterally extends on the bottom surface of the dielectric layer and is electrically coupled to the bottom ends of the metal leads and extends into the through openings; and a plurality of electroplated etching stoppers that project from the floor of the cavity and extend into the through openings and contact the routing circuitry in the through openings of the dielectric layer.

In another aspect, the present invention provides another interconnect substrate, comprising: a plurality of metal leads that laterally surround a predetermined area and each have a top end and a bottom end; a resin compound that fills in spaces between the metal leads and laterally extends into the predetermined area to laterally surround a periphery of cavity at the predetermined area and has a top surface adjacent to an entrance of the cavity; a dielectric layer that covers a floor of the cavity and has a bottom surface positioned at a level below the floor of the cavity; a plurality of through openings that are aligned with the cavity and disposed in the dielectric layer; a routing circuitry that laterally extends on the bottom surface of the dielectric layer and is electrically coupled to the bottom ends of the metal leads and extends into the through openings and projects from the floor of the cavity to form a plurality of protruded bumps located above the floor of the cavity; and a plurality of electroplated etching stoppers that contact and cover the protruded bumps of the routing circuitry.

In yet another aspect, the present invention provides a method of making an interconnect substrate, comprising: providing a leadframe that includes a metal frame, a metal slug and metal leads, wherein the metal slug is located within the metal frame, and the metal leads laterally surround the metal slug and are located between the metal frame and the metal slug; providing a resin compound that fills in remaining spaces within the metal frame and providing a dielectric layer that covers a bottom end of the metal slug, wherein the dielectric layer has a bottom surface positioned at a level below the bottom end of the metal slug; forming through openings that are aligned with the metal slug and extend from the bottom surface of the dielectric layer to the bottom end of the metal slug; forming pits that are aligned with the through openings and extend from the bottom end of the metal slug to a predetermined depth within the metal slug; forming etching stoppers in the pits of the metal slug; forming a routing circuitry that is electrically connected to bottom ends of the metal leads and extends into the through openings and contacts the etching stoppers; and removing the metal slug to form a cavity and to expose the etching stoppers from the cavity, wherein the cavity has a floor positioned at a level between the top surface of the resin compound and the bottom surface of the dielectric layer.

Additionally, the present invention also provides a semiconductor assembly, comprising: the aforementioned interconnect substrate and a first semiconductor device disposed in the cavity of the interconnect substrate and electrically connected to the electroplated etching stoppers.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1, 2 and 3 are cross-sectional, top perspective and bottom perspective views, respectively, of a leadframe in accordance with the first embodiment of the present invention;

FIGS. 4 and 5 are cross-sectional and top perspective views, respectively, of the structure of FIGS. 1, 2 and 3 further provided with a resin compound and a dielectric layer in accordance with the first embodiment of the present invention;

FIG. 6 is a cross-sectional view of the structure of FIGS. 4 and 5 further provided with through openings in accordance with the first embodiment of the present invention;

FIG. 7 is a cross-sectional view of the structure of FIG. 6 further provided with pits in accordance with the first embodiment of the present invention;

FIG. 8 is an enlarged view of a circled portion in FIG. 7;

FIG. 9 is a cross-sectional view of the structure of FIG. 7 further provided with etching stoppers in accordance with the first embodiment of the present invention;

FIG. 10 is an enlarged view of a circled portion in FIG. 9;

FIG. 11 is a cross-sectional view of the structure of FIG. 9 further provided with a routing circuitry in accordance with the first embodiment of the present invention;

FIG. 12 is an enlarged view of a circled portion in FIG. 11;

FIGS. 13, 14 and 15 are cross-sectional, top and bottom perspective views, respectively, of the structure of FIG. 11 further formed with a cavity to finish the fabrication of an untrimmed interconnect substrate in accordance with the first embodiment of the present invention;

FIGS. 16 and 17 are cross-sectional and top perspective views, respectively, of a semiconductor assembly having a first semiconductor device electrically connected to the interconnect substrate of FIGS. 13, 14 and 15 in accordance with the first embodiment of the present invention;

FIGS. 18 and 19 are cross-sectional and top perspective views, respectively, of the structure of FIGS. 16 and 17 after a trimming process in accordance with the first embodiment of the present invention;

FIG. 20 is a cross-sectional view of the structure of FIG. 18 further provided with another semiconductor assembly and solder balls in accordance with the first embodiment of the present invention;

FIG. 21 is a cross-sectional view of the structure of FIG. 18 further provided with a second semiconductor device, bonding wires, an encapsulant and solder balls in accordance with the first embodiment of the present invention;

FIG. 22 is a cross-sectional view of the structure of FIG. 7 further provided with etching stoppers in accordance with the second embodiment of the present invention;

FIG. 23 is an enlarged view of a circled portion in FIG. 22;

FIG. 24 is a cross-sectional view of the structure of FIG. 22 further provided with a routing circuitry in accordance with the second embodiment of the present invention;

FIG. 25 is an enlarged view of a circled portion in FIG. 24;

FIGS. 26 and 27 are cross-sectional and top perspective views, respectively, of the structure of FIG. 24 further formed with a cavity to finish the fabrication of an untrimmed interconnect substrate in accordance with the second embodiment of the present invention;

FIG. 28 is a cross-sectional view of a semiconductor assembly having a first semiconductor device electrically connected to the interconnect substrate of FIGS. 26 and 27 in accordance with the second embodiment of the present invention;

FIG. 29 is a cross-sectional view of the structure of FIG. 28 further provided with another semiconductor assembly in accordance with the second embodiment of the present invention;

FIG. 30 is a cross-sectional view of the structure of FIG. 28 further provided with a second semiconductor device, bonding wires and an encapsulant in accordance with the second embodiment of the present invention;

FIG. 31 is a cross-sectional view of the structure of FIG. 11 further provided with a connecting circuitry in accordance with the third embodiment of the present invention;

FIG. 32 is a cross-sectional view of the structure of FIG. 31 further formed with a cavity to finish the fabrication of an untrimmed interconnect substrate in accordance with the third embodiment of the present invention;

FIG. 33 is a cross-sectional view of another aspect of the untrimmed interconnect substrate in accordance with the third embodiment of the present invention;

FIG. 34 is a cross-sectional view of a leadframe in accordance with the fourth embodiment of the present invention;

FIG. 35 is a cross-sectional view of the structure of FIG. 34 further provided with a resin compound and a dielectric layer in accordance with the fourth embodiment of the present invention;

FIG. 36 is a cross-sectional view of the structure of FIG. 35 further provided with through openings in accordance with the fourth embodiment of the present invention;

FIG. 37 is a cross-sectional view of the structure of FIG. 36 further provided with pits in accordance with the fourth embodiment of the present invention;

FIG. 38 is a cross-sectional view of the structure of FIG. 37 further provided with etching stoppers in accordance with the fourth embodiment of the present invention;

FIG. 39 is a cross-sectional view of the structure of FIG. 38 further provided with a routing circuitry in accordance with the fourth embodiment of the present invention;

FIG. 40 is a cross-sectional view of the structure of FIG. 39 further formed with a cavity to finish the fabrication of an untrimmed interconnect substrate in accordance with the fourth embodiment of the present invention; and

FIG. 41 is a cross-sectional view of another aspect of the untrimmed interconnect substrate in accordance with the fourth embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

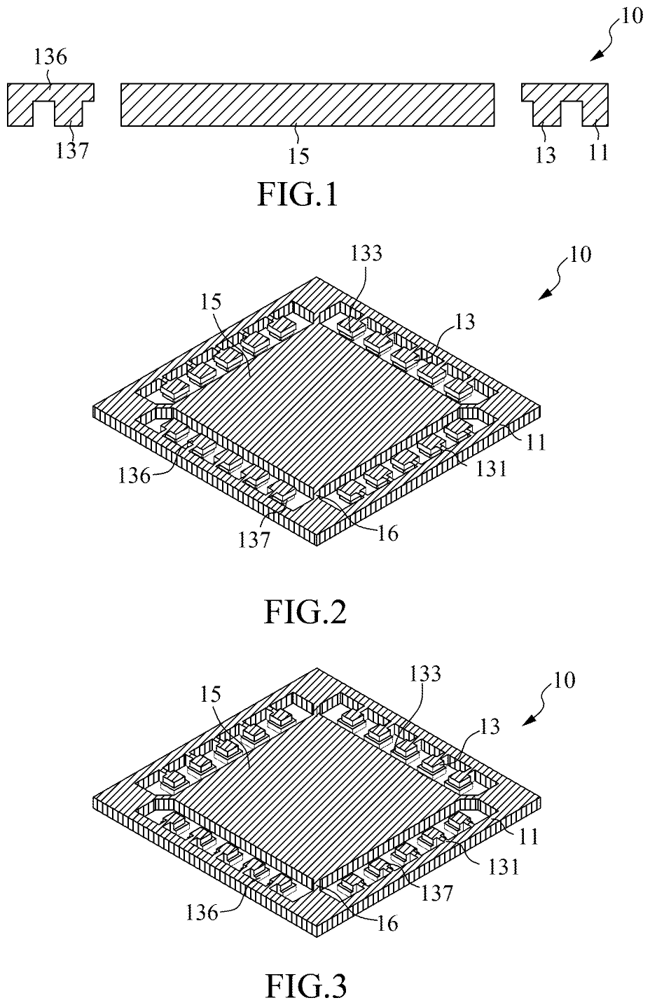

FIGS. 1-15 are schematic views showing a method of making an interconnect substrate that includes a metal frame, a plurality of metal leads, a plurality of tie bars, a resin compound, a dielectric layer, a plurality of etching stoppers and a routing circuitry in accordance with the first embodiment of the present invention.

FIGS. 1, 2 and 3 are cross-sectional, top and bottom perspective views, respectively, of a leadframe 10. The leadframe 10 typically is made of copper and can be formed by a wet etching or stamping/punching process from a rolled metal strip having a thickness in a range from about 0.15 mm to about 1.0 mm. The etching process may be a one-sided or two-sided etching to etch through the metal strip and thereby transfer the metal strip into a desired overall pattern of the leadframe 10 that includes a metal frame 11, a plurality of metal leads 13, a metal slug 15 and a plurality of tie bars 16. In this illustration, the metal leads 13 laterally extend from the metal frame 11 toward the central area within the metal frame 11. As a result, the metal leads 13 each have an outer end 131 integrally connected to interior sidewalls of the metal frame 11 and an inner end 133 directed inwardly away from the metal frame 11. The metal slug 15 is located at the central area within the metal frame 11 and connected to the metal frame 11 by the tie bars 16. Additionally, in this embodiment, the leadframe 10 is further selectively half-etched from its bottom end. Accordingly, the metal leads 13 have stepped peripheral edges. The metal leads 13 each have a horizontally elongated portion 136 and a vertically projected portion 137. The vertically projected portion 137 protrudes from a lower surface of the horizontally elongated portion 136 in the downward direction.

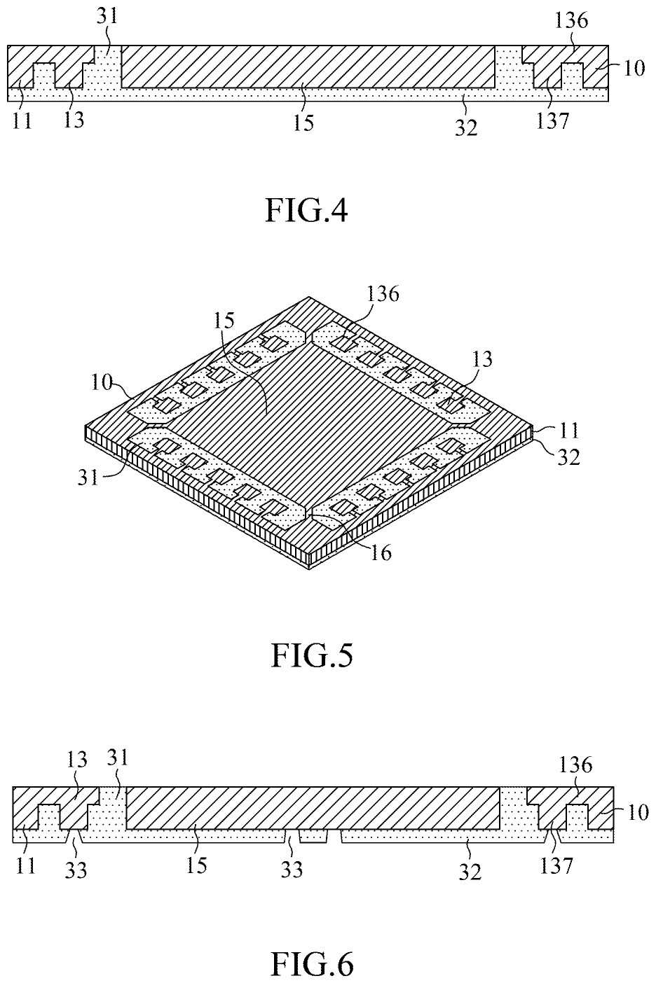

FIGS. 4 and 5 are cross-sectional and top perspective views, respectively, of the structure provided with a resin compound 31 and a dielectric layer 32. The resin compound 31 fills in spaces between the metal leads 13 and between the metal slug 15 and the metal leads 13, whereas the dielectric layer 32 covers the bottom ends of the metal frame 11, the metal leads 13 and the metal slug 15. The resin compound 31 and the dielectric layer 32 can be integrally formed by applying a resin material to fill in the remaining spaces within the metal frame 11 and cover the leadframe 10 from below. The resin material can be applied by various techniques, including but not limited to, paste printing, compressive molding, transfer molding, liquid injection molding or spin coating, followed by a thermal process (or heat-hardened process) to harden the resin material and to transform it into a solid molding compound. By the stepped cross-section profile of the metal leads 13, the resin compound 31 can securely interlock with the metal leads 13 so as to prevent the metal leads 13 from being vertically forced apart from the resin compound 31 and also to avoid micro-cracking at the interface along the vertical direction. In this illustration, the top surface of the resin compound 31 is substantially coplanar with the top ends of the metal leads 13, the metal slug 15 and the tie bars 16, while the bottom surface of the dielectric layer 32 is positioned at a level below the bottom ends of the metal leads 13, the metal slug 15 and the tie bars 16.

FIG. 6 is a cross-sectional view of the structure provided with through openings 33 to expose selected portions of the metal leads 13 and the metal slug 15 from below. The through openings 33 are formed by numerous techniques including laser drilling, plasma etching and photolithography, and typically have a diameter of 50 microns. Laser drilling can be enhanced by a pulsed laser. Alternatively, a scanning laser beam with a metal mask can be used. The through openings 33 are formed in the dielectric layer 32, and are aligned with selected portions of the vertically projected portions 137 of the metal leads 13 and the metal slug 15. In this illustration, each of the through openings 33 has a diameter that decreases as it extends from the bottom surface of the dielectric layer 32 to the bottom ends of the metal leads 13 and the metal slug 15.

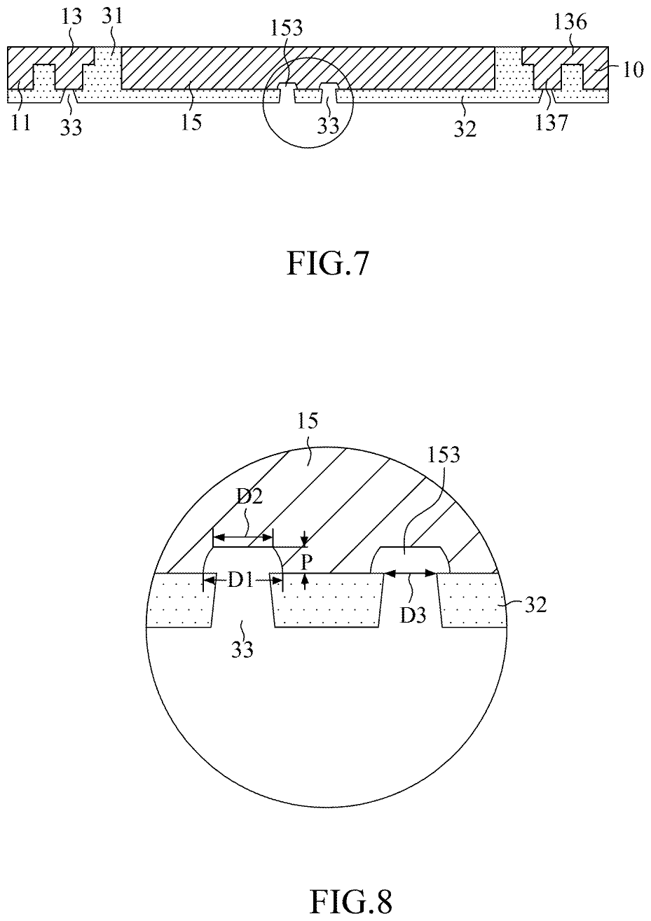

FIG. 7 is a cross-sectional view of the structure provided with pits 153 in the metal slug 15, while FIG. 8 is an enlarged view of a circled portion in FIG. 7. The pits 153 can be formed by, for example, etching of the metal slug 15, and typically have a depth P of at least about 5 micrometers. The pits 153 are formed in the metal slug 15 and aligned with and communicated with the through openings 33 therebelow. Each of the pits 153 has an open end at the bottom end of the metal slug 15 and an opposite closed end at a level above the bottom end of the metal slug 15. As shown In FIG. 8, the diameter D1 of the open end of the pits 153 is larger than the diameter D2 of the closed end of the pits 153 and the diameter D3 of the through openings 33 at the interface between the metal slug 15 and the dielectric layer 32.

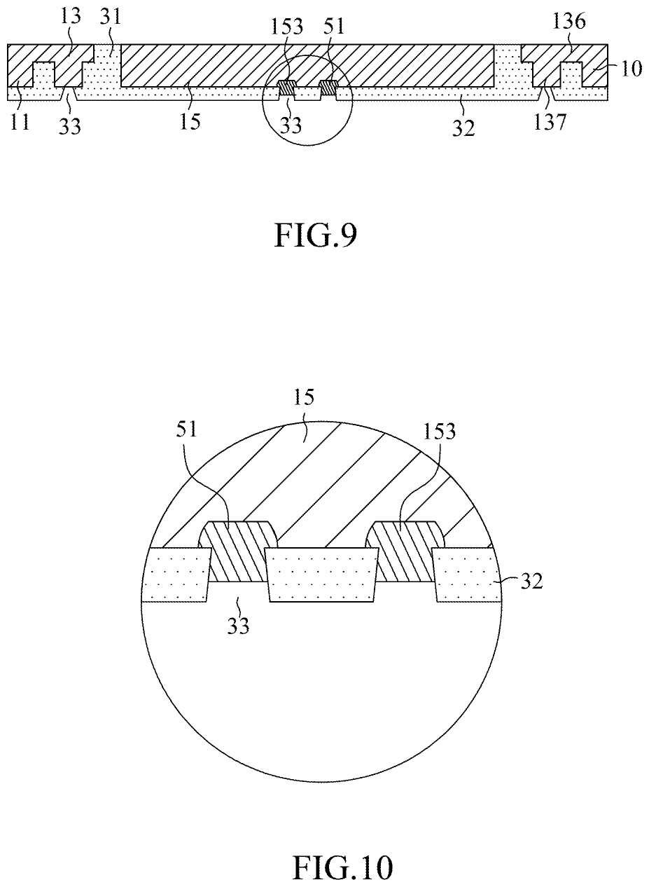

FIG. 9 is a cross-sectional view of the structure provided with etching stoppers 51, while FIG. 10 is an enlarged view of a circled portion in FIG. 9. By applying the voltage on the metal frame 11, the metal slug 15, in electrical connection with the metal frame 11 through the tie bars 16, can serve as a cathode for electrodeposition of the etching stoppers 51 in the pits 153. The electroplated etching stoppers 51 fill up the pits 153 and extend into the through openings 33 located below the pits 153. Typically, the etching stoppers 51 have a higher etch resistance than the leadframe 10 under alkaline copper-etching chemistry required for subsequent removal process of the metal slug 15.

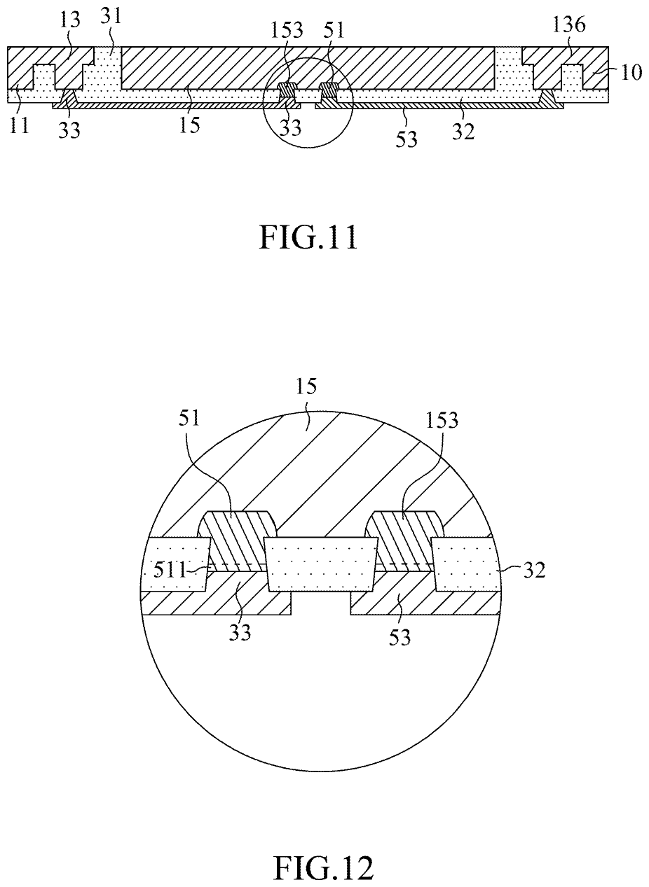

FIG. 11 is a cross-sectional view of the structure provided with a routing circuitry 53, while FIG. 12 is an enlarged view of a circled portion in FIG. 11. In this embodiment, the routing circuitry 53 is illustrated as a patterned metal layer formed by metal deposition and metal patterning process. The routing circuitry 53 extends from the metal leads 13 and the etching stoppers 51 in the downward direction, fills up the through openings 33, and extends laterally on the bottom surface of the dielectric layer 32. As a result, the routing circuitry 53 is electrically connected to the metal leads 13 and the etching stoppers 51 and provides horizontal routing in both the X and Y directions. The material of the routing circuitry 53 typically is the same as that of the leadframe 10 and different from that of the etching stoppers 51. More specifically, the etching stoppers 51 preferably have a higher etch resistance than the routing circuitry 53 under alkaline copper-etching chemistry and have sufficient thickness of at least about 5 micrometers to ensure no routing circuitry 53 being damaged during the subsequent removal of the metal slug 15. In this embodiment, the etching stoppers 51 include a metal that has a melting point lower than that of the routing circuitry 53. Further, due to element diffusion during the deposition of the routing circuitry 53, the etching stoppers 51 typically form an interfacial material layer 511 (shown in FIG. 12) at the boundary between the etching stoppers 51 and the routing circuitry 53.

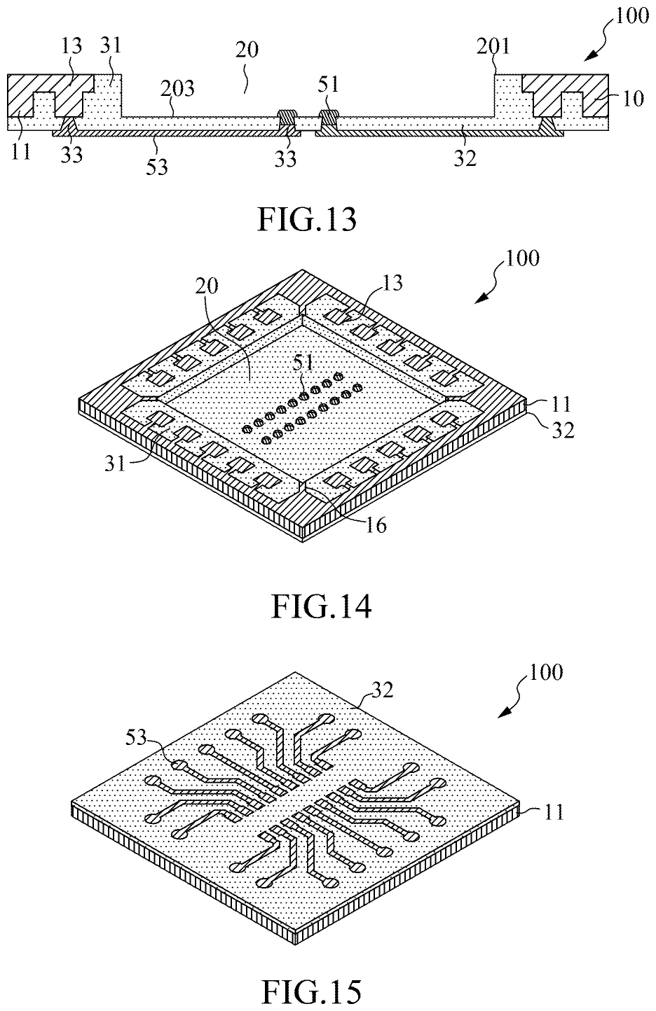

FIGS. 13, 14 and 15 are cross-sectional, top and bottom perspective views, respectively, of the structure after removal of the metal slug 15. The metal slug 15 can be entirely removed by, for example, chemical etching, to form a cavity 20 that has an entrance 201 at the top surface of the resin compound 31 and a floor 203 positioned at a level between the top surface of the resin compound 31 and the bottom surface of the dielectric layer 32 and substantially coplanar with the bottom ends of the metal leads 13. As a result, the etching stoppers 51 are exposed from the cavity 20 and project from the floor 203 of the cavity 20 so as to provide electrical contacts for device connection within the cavity 20.

At this stage, an untrimmed interconnect substrate 100 is accomplished and includes the metal frame 11, the metal leads 13, the tie bars 16, the resin compound 31, the dielectric layer 32, the etching stoppers 51 and the routing circuitry 53. The metal leads 13 are integrated with and located within the metal frame 11 and laterally surround the predetermined area for device placement. The resin compound 31 fills in spaces between the metal leads 13 and laterally extends to the predetermined area to laterally surround the cavity 20 at the predetermined area. The dielectric layer 32 covers the floor 203 of the cavity 20, the resin compound 31, the metal leads 13, the tie bars 16 and the metal frame 11 from below. The tie bars 16 are integrated with the metal frame 11 and placed around the periphery of the cavity 20. Each of the electroplated etching stoppers 51 has an upper portion above the floor 203 of the cavity 20 and a lower portion in the through opening 33 aligned with the cavity 20. The routing circuitry 53 extends laterally on the bottom surface of the dielectric layer 32 and extends into the through openings 33 and contact the metal leads 13 and the etching stoppers 51. As the etching stoppers 51 can be electroplated to sufficient thickness by applying voltage on the metal frame 11, the integrity of electrical contacts provided at the floor 203 of the cavity 20 can be ensured during the cavity formation. In this embodiment, the electroplated etching stoppers 51 extend into the through openings 33 located below the cavity 20 and form an interfacial material layer 511, as illustrated in FIG. 21, at a level between the floor 203 of the cavity 20 and the bottom surface of the dielectric layer 32.

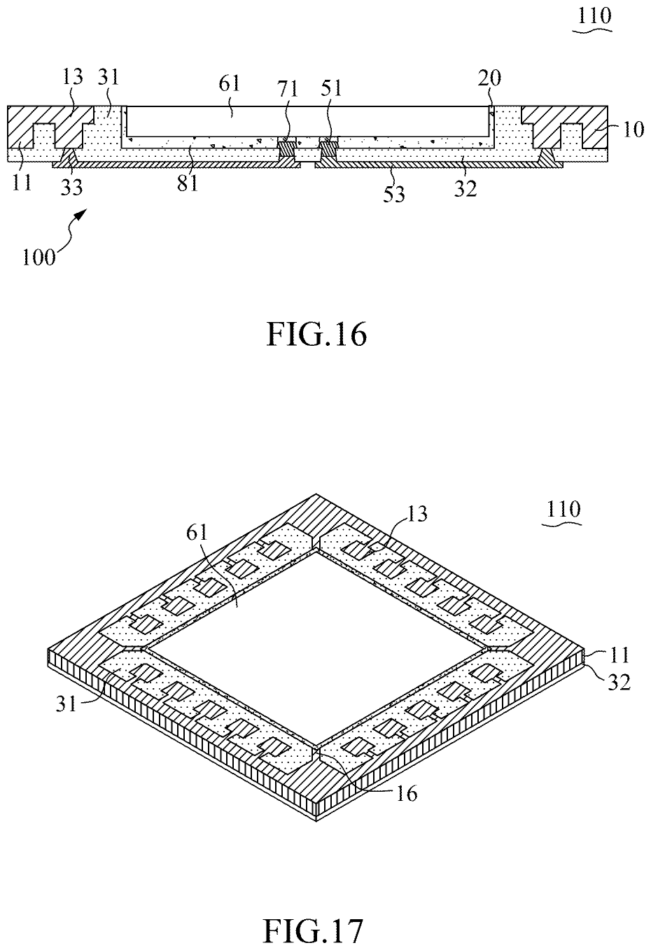

FIGS. 16 and 17 are cross-sectional and top perspective views, respectively, of a semiconductor assembly 110 with a first semiconductor device 61 electrically coupled to the interconnect substrate 100. The first semiconductor device 61, illustrated as a chip, is face-down disposed in the cavity 20 and electrically coupled to the etching stoppers 51 through conductive bumps 71 in contact with the planar top surface and tapered sidewalls of the etching stoppers 51. As a result, the first semiconductor device 61 is electrically connected to the metal leads 13 through the etching stoppers 51 and the routing circuitry 53. Optionally, an underfill 81 may be dispensed in the remaining space within the cavity 20.

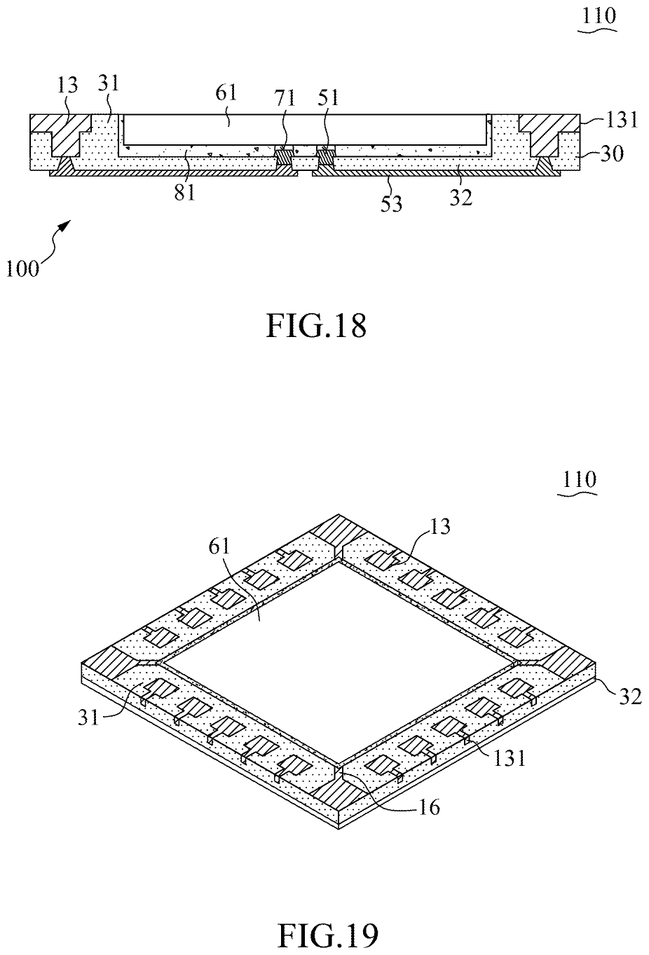

FIGS. 18 and 19 are cross-sectional and top perspective views, respectively, of the semiconductor assembly 110 of FIGS. 16 and 17 after removal of the metal frame 11 as well as the peripheral portion of the dielectric layer 32. Removal of the metal frame 11 can be done by various methods including chemical etching, mechanical trimming/cutting or sawing to separate the metal frame 11 from the outer ends 131 of the metal leads 13. As a result, the outer ends 131 of the metal leads 13 are situated at peripheral edges of the trimmed interconnect substrate 100 and have a lateral surface flush with peripheral edges of the resin compound 31 and the dielectric layer 32.

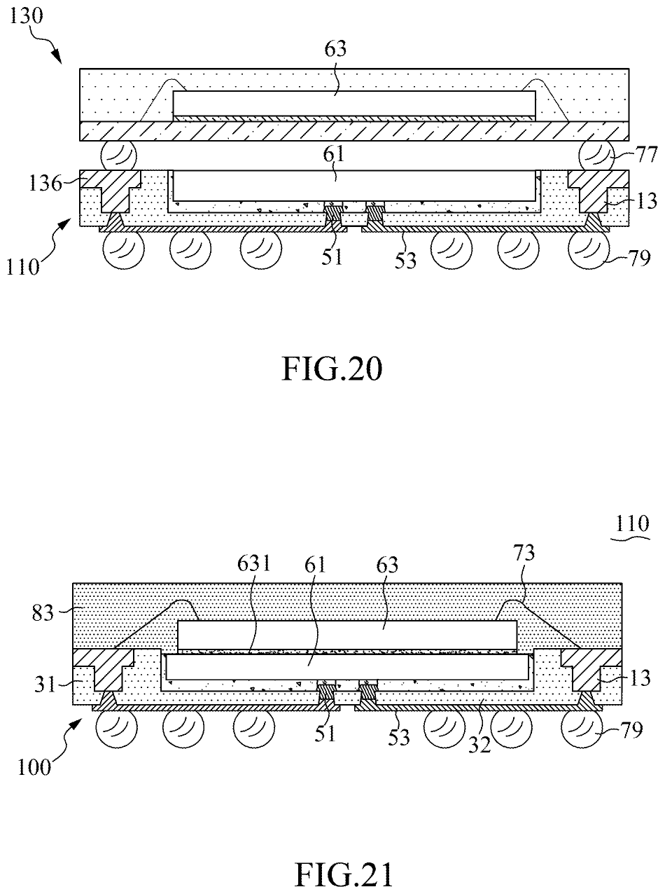

FIG. 20 is a cross-sectional view of the semiconductor assembly 110 of FIG. 18 further provided with another semiconductor assembly 130 stacked thereon. The upper semiconductor assembly 130 includes a second semiconductor device 63 packaged therein and is stacked on and electrically coupled to the lower semiconductor assembly 110 by solder balls 77 in contact with the horizontally elongated portions 136 of the metal leads 13 of the lower semiconductor assembly 110. Further, additional solder balls 79 are mounted on the routing circuitry 53 of the lower semiconductor assembly 110.

FIG. 21 is a cross-sectional view of the semiconductor assembly 110 of FIG. 18 further provided with a second semiconductor device 63, bonding wires 73 and an encapsulant 83. The second semiconductor device 63, illustrated as a chip, is face-up attached on the first semiconductor device 61 through an adhesive 631 and electrically coupled to the metal leads 13 through the bonding wires 73. Further, solder balls 79 are mounted on the routing circuitry 53 for next-level electrical connection. Optionally, the encapsulant 83 may be further provided to cover and encapsulate the second semiconductor device 63 and the bonding wires 73 from above and laterally extend to peripheral edges of the interconnect substrate 100.

### Embodiment 2

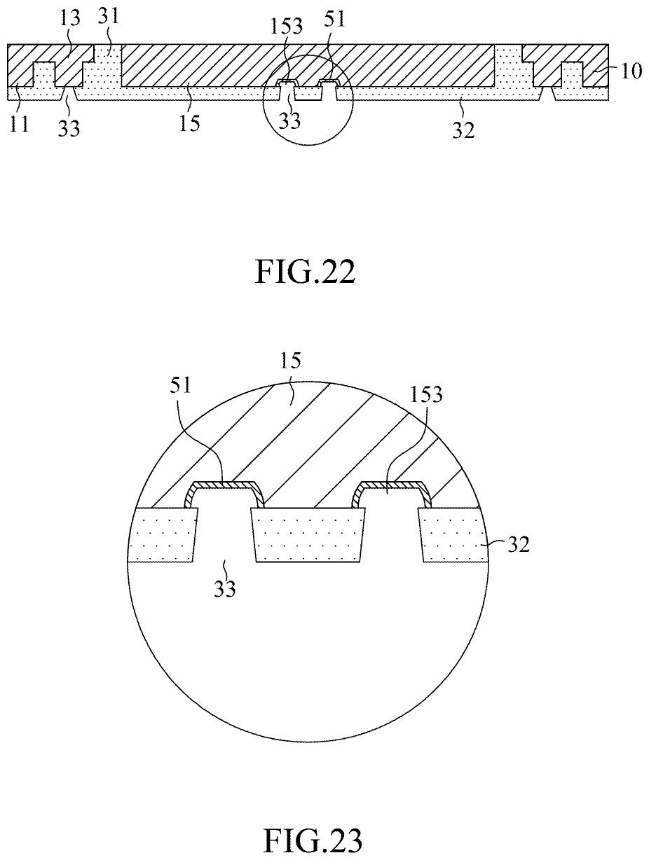

FIGS. 22-27 are schematic views showing a method of making another interconnect substrate in accordance with the second embodiment of the present invention.

For purposes of brevity, any description in Embodiment 1 is incorporated herein insofar as the same is applicable, and the same description need not be repeated.

FIG. 22 is a cross-sectional view of the structure of FIG. 7 further provided with etching stoppers 51 in the pits 153, while FIG. 23 is an enlarged view of a circled portion in FIG. 22. In this illustration, the etching stoppers 51 are electroplated on the walls of the pits 153 to form layer-like etching barriers in a thickness of at least about 0.5 micrometer. As a result, the remaining spaces in the pits 153 are spaced from the metal slug 15 by the electroplated etching stoppers 51.

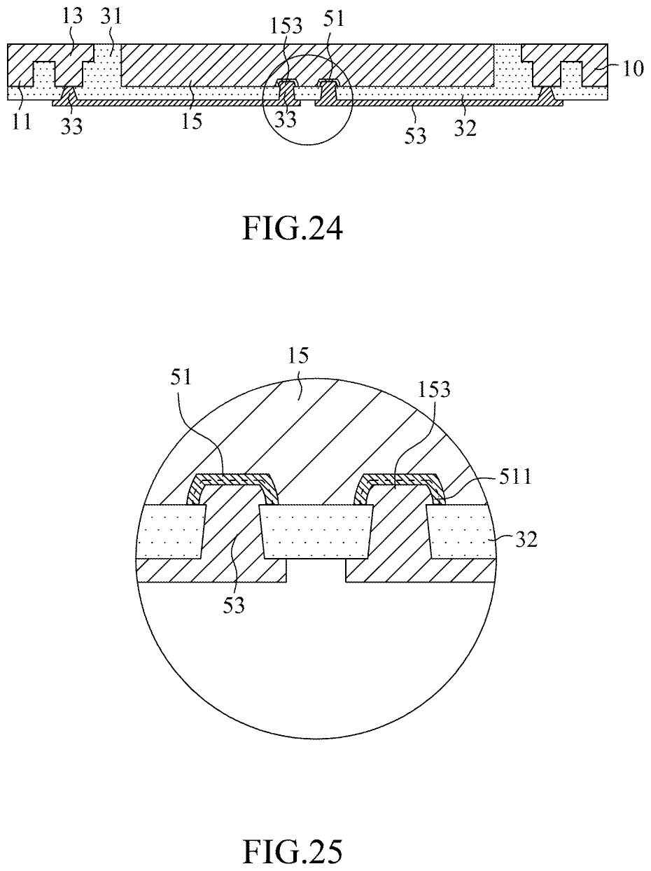

FIG. 24 is a cross-sectional view of the structure further provided with a routing circuitry 53, while FIG. 25 is an enlarged view of a circled portion in FIG. 24. The routing circuitry 53 extends from the etching stoppers 51 and the metal leads 13 in the downward direction, fills up the through openings 33 as well as the remaining spaces of the pits 153, and extends laterally on the bottom surface of the dielectric layer 32. As shown in FIG. 25, due to element diffusion during the deposition of the routing circuitry 53, the etching stoppers 51 typically form an interfacial material layer 511 at the boundary between the etching stoppers 51 and the routing circuitry 53.

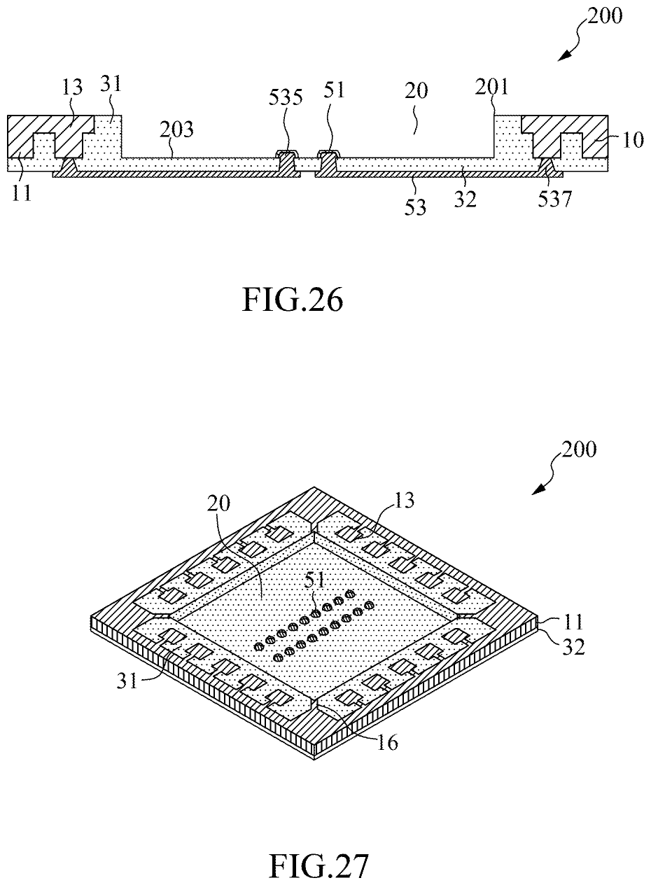

FIGS. 26 and 27 are cross-sectional and top perspective views, respectively, of the structure after removal of the metal slug 15. By the removal of the metal slug 15, a cavity 20 is formed and allows a device to be displaced therein and to be electrically connected to protruded bumps 535 provided by the routing circuitry 53 and located above the floor 203 of the cavity 20.

Accordingly, an untrimmed interconnect substrate 200 is accomplished and includes the metal frame 11, the metal leads 13, the tie bars 16, the resin compound 31, the dielectric layer 32, the etching stoppers 51 and the routing circuitry 53. The metal leads 13 and the tie bars 16 are integrated with the metal frame 11 and spaced from each other by the resin compound 31 and positioned around the periphery of the cavity 20. The resin compound 31 has a top surface adjacent to the entrance 201 of the cavity 20, whereas the dielectric layer 32 has a bottom surface positioned at a level below of the floor 203 of the cavity 20. The routing circuitry 53 is electrically connected to the metal leads 13 through conductive vias 537 and has selected portions projecting from the floor 203 of the cavity 20 to form protruded bumps 535 as electrical contacts for device connection. In order to protect the protruded bumps 535 from being damaged during the cavity formation, the etching stoppers 51 completely cover the protruded bumps 535 from above and forms an interfacial material layer 511, as illustrated in FIG. 25, at a level above the floor 203 of the cavity 20.

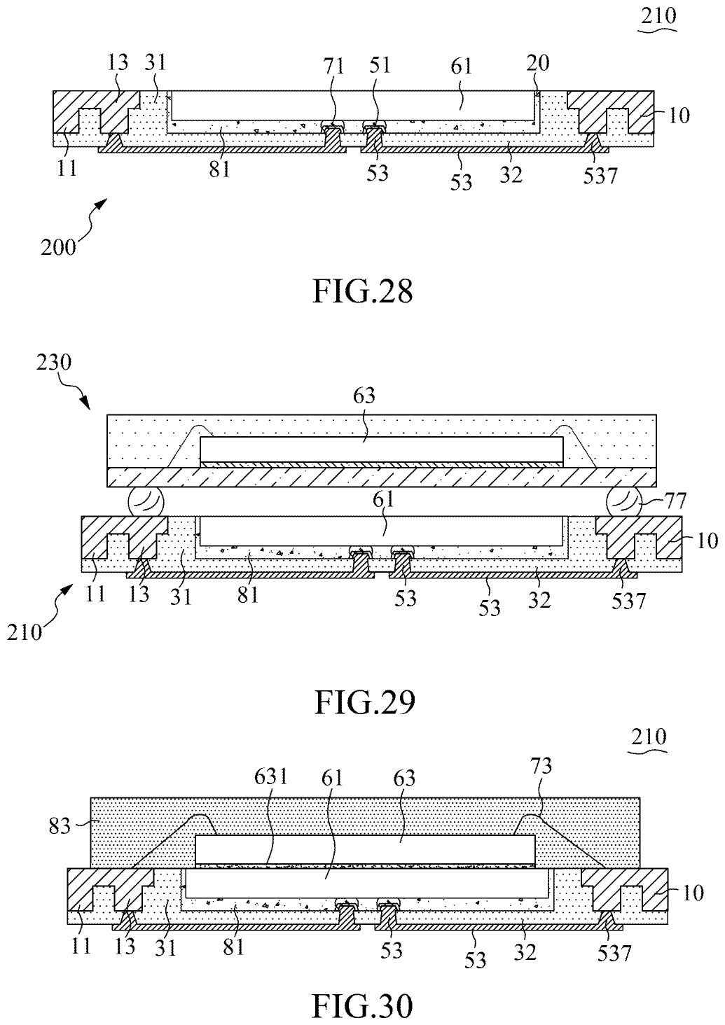

FIG. 28 is a cross-sectional view of a semiconductor assembly 210 with a first semiconductor device 61 electrically coupled to the interconnect substrate 200 through conductive bumps 71. The first semiconductor device 61 is face-down disposed in the cavity 20 and electrically coupled to the routing circuitry 53 through the etching stoppers 51 and the conductive bumps 71. Optionally, an underfill 81 may be dispensed in the remaining space within the cavity 20.

FIG. 29 is a cross-sectional view of the semiconductor assembly 210 of FIG. 28 further provided with another semiconductor assembly 230. The upper semiconductor assembly 230 includes a second semiconductor device 63 packaged therein and is stacked on and electrically coupled to the lower semiconductor assembly 210 by solder balls 77 in contact with the top ends of the metal leads 13 of the lower semiconductor assembly 210.

FIG. 30 is a cross-sectional view of the semiconductor assembly 210 of FIG. 28 further provided with a second semiconductor device 63, bonding wires 73 and an encapsulant 83. The second semiconductor device 63 is face-up disposed over the first semiconductor device 61 through an adhesive 631 and electrically coupled to the metal leads 13 through the bonding wires 73. Optionally, the encapsulant 83 may be further provided to cover and encapsulate the second semiconductor device 63 and the bonding wires 73 from above.

### Embodiment 3

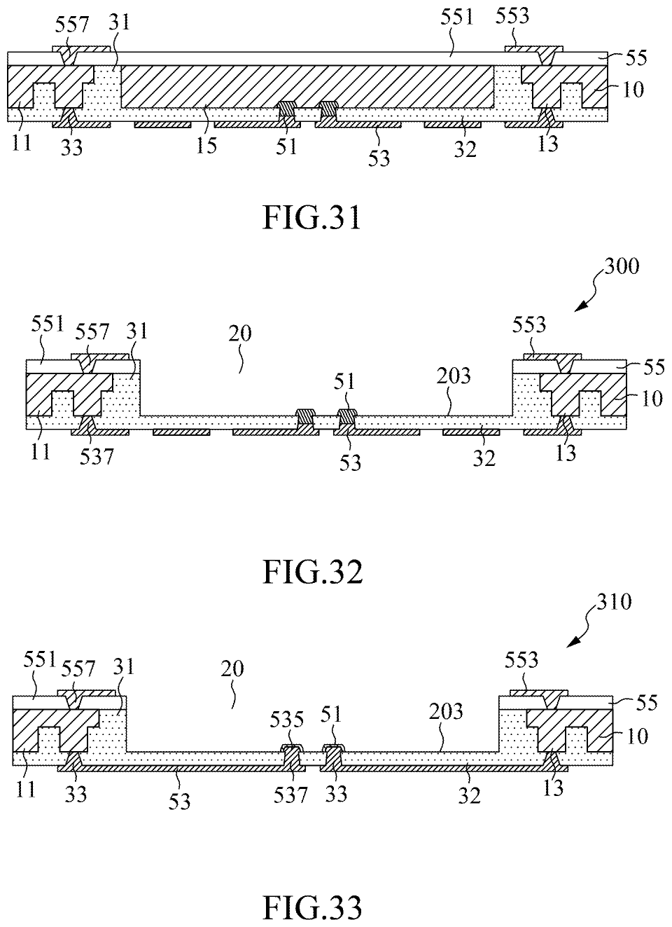

FIGS. 31-32 are schematic views showing a method of making yet another interconnect substrate in accordance with the third embodiment of the present invention.

For purposes of brevity, any description in the Embodiments above is incorporated herein insofar as the same is applicable, and the same description need not be repeated.

FIG. 31 is a cross-sectional view of the structure of FIG. 11 further provided with a connecting circuitry 55 disposed over the top surface of the resin compound 31 as well as the top end of the leadframe 10 and electrically coupled to the top ends of the metal leads 13. In this embodiment, the connecting circuitry 55 is illustrated as a multi-layered build-up circuitry and includes an insulating layer 551 and a routing layer 553 serially formed in an alternate fashion. The insulating layer 551 contacts and covers and extends laterally on the top surface of the resin compound 31 as well as the top end of the leadframe 10 from above. The routing layer 553 extends laterally on the insulating layer 551 to provide the top electrical contacts for next-level electrical connection and includes metallized vias 557 in direct contact with the metal leads 13.

FIG. 32 is a cross-sectional view of the structure formed with a cavity 20 to finish the fabrication of an untrimmed interconnect substrate 300. The cavity 20 is formed by removing a selected portion of the connecting circuitry 55 and the metal slug 15. As a result, the resin compound 31 and the connecting circuitry 55 have inner sidewalls that laterally surround the cavity 20 from which the etching stoppers 51 are exposed for device connection.

FIG. 33 is a cross-sectional view of another aspect of the untrimmed interconnect substrate according to the third embodiment of the present invention. The untrimmed wiring substrate 310 is similar to that illustrated in FIG. 32, except that the etching stoppers 51 do not extend into the through openings 33 and the routing circuitry 53 has protruded bumps 535 above the floor 203 of the cavity 20 and conductive vias 537 in the through openings 33. The diameter of the protruded bumps 535 decrease as it upwardly extends from the floor 203 of the cavity 20, whereas the diameter of the conductive vias 537 increase as it downwardly extends from the floor 203 of the cavity 20.

### Embodiment 4

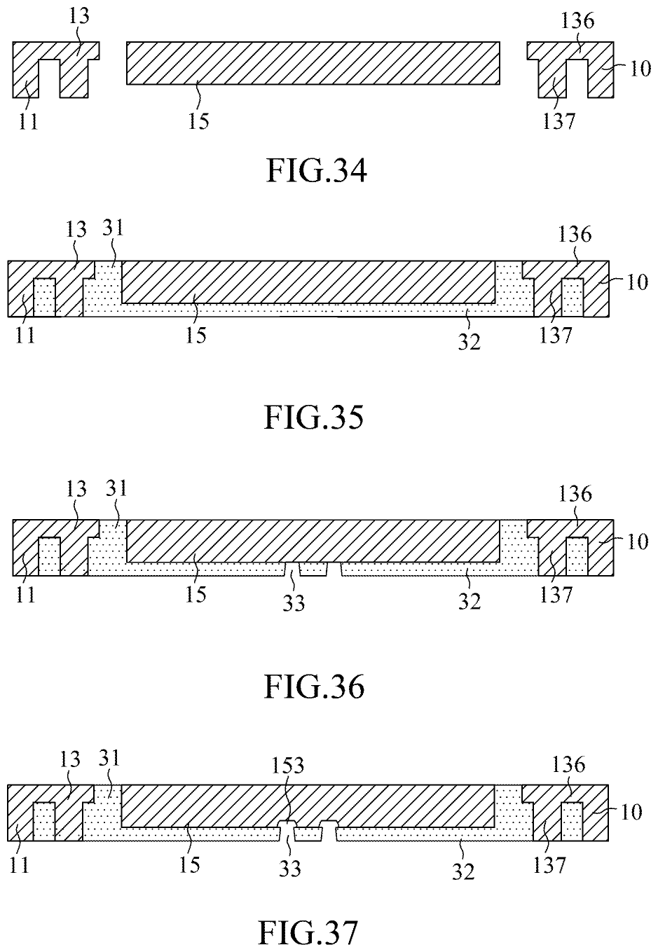

FIGS. 34-40 are schematic views showing a method of making yet another interconnect substrate in accordance with the fourth embodiment of the present invention.

FIG. 34 is a cross-sectional view of a leadframe 10. The leadframe 10 is similar to that illustrated in FIGS. 1-3, except that the metal slug 15 is thinner than the metal frame 11 and the metal leads 13.

FIG. 35 is a cross-sectional view of the structure provided with a resin compound 31 and a dielectric layer 32. The resin compound 31 covers the lower surfaces of the horizontally elongated portions 136 as well as sidewalls of the vertically projected portions 137 and sidewalls of the metal slug 15. The dielectric layer 32 covers the bottom end of the metal slug 15 from below and is integral with the resin compound 31. The resin compound 31 and the dielectric layer 32 can be integrally formed by applying a resin material into the remaining spaces within the metal frame 11. By planarization, the resin compound 31 has a top surface substantially coplanar with the top ends of the metal frame 11, the metal leads 13 and the metal slug 15, whereas the dielectric layer 32 has a bottom surface substantially coplanar with the bottom surface of the resin compound 31 and the bottom ends of the metal frame 11 and the metal leads 13.

FIG. 36 is a cross-sectional view of the structure provided with through openings 33. The through openings 33 extend through the dielectric layer 32 and are aligned with selected portions of the metal slug 15. In this illustration, each of the through openings 33 has a diameter that decreases as it extends from the bottom surface of the dielectric layer 32 to the bottom ends of the metal slug 15.

FIG. 37 is a cross-sectional view of the structure provided with pits 153 in the metal slug 15. The pits 153 are formed at the bottom end of the metal slug 15 and aligned with the through opening 33. Each of the pits 153 has a diameter that decreases as it extends in the upward direction from the bottom end of the metal slug 15 to a predetermined depth within the metal slug 15. Further, at the bottom end of the metal slug 15, the diameter of the pits 153 is larger than that of the through openings 33.

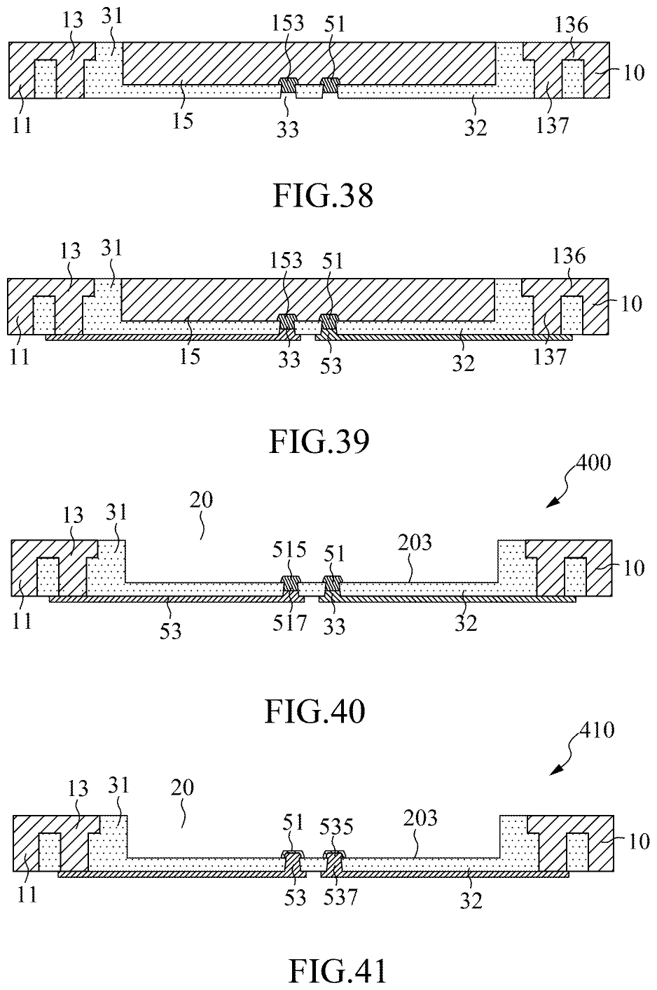

FIG. 38 is a cross-sectional view of the structure provided with etching stoppers 51 formed by electroplating. The etching stoppers 51 fill up the pits 153 and extend into the through openings 33. As a result, each of the etching stoppers 51 has an upper portion in the pit 153 and a lower portion in the through opening 33.

FIG. 39 is a cross-sectional view of the structure provided with a routing circuitry 53 formed by metal deposition and metal patterning process. The routing circuitry 53 fills up the remaining spaces of the through openings 33 and laterally extends on the bottom surface of the resin compound 31 and the dielectric layer 32 and is electrically coupled to the bottom ends of the metal leads 13 and the etching stoppers 51.

FIG. 40 is a cross-sectional view of the structure after removal of the metal slug 15. The metal slug 15 is entirely removed to finish the fabrication of an untrimmed interconnect substrate 400 having electrical contacts exposed from a cavity 20. In this embodiment, the etching stoppers 51 have protruded portions 515 located above the floor 203 of the cavity 20 to provide the electrical contacts for device connection and embedded portions 517 located in the through openings 33 of the dielectric layer 32 and in contact with the routing circuitry 53 for electrical connection with the metal leads 13. As illustrated in FIG. 40, the protruded portions 515 and the embedded portions 517 of the etching stoppers 51 have tapered sidewalls, and the bottom diameter of the protruded portions 515 is larger than the top diameter of the embedded portions 517. More specifically, the diameter of the protruded portions 515 decrease as it upwardly extends from the floor 203 of the cavity 20, whereas the diameter of the embedded portions 517 increase as it downwardly extends from the floor 203 of the cavity 20.

FIG. 41 is a cross-sectional view of another aspect of the untrimmed interconnect substrate according to the fourth embodiment of the present invention. The untrimmed wiring substrate 410 is similar to that illustrated in FIG. 40, except that the routing circuitry 53 has selected portions projecting from the floor 203 of the cavity 20. In this aspect, the routing circuitry 53 has protruded bumps 535 spaced from the cavity 20 by the etching stoppers 51 and conductive vias 537 in the dielectric layer 32. As shown in FIG. 40, the protruded bumps 535 and the conductive vias 537 have tapered sidewalls, and the bottom diameter of the protruded bumps 535 is larger than the top diameter of the conductive vias 537. As the planar top surface and tapered sidewalls of the protruded bumps 535 are completely covered and protected by the etching stoppers 51, the integrity of the protruded bumps 535 can be ensured during cavity formation.

As illustrated in the aforementioned embodiments, a distinctive interconnect substrate is configured to exhibit improved reliability, which mainly includes a plurality of metal leads, a resin compound, a dielectric layer, a plurality of etching stoppers, a routing circuitry and optionally a connecting circuitry. The interconnect substrates and assemblies described above are merely exemplary. Numerous other embodiments are contemplated. In addition, the embodiments described above can be mixed-and-matched with one another and with other embodiments depending on design and reliability considerations.

The interconnect substrate has a cavity formed typically after formation of the routing circuitry by removing a metal slug of a leadframe combined with the resin compound and the dielectric layer. As a result, the cavity is laterally surrounded by the resin compound and has a floor covered by the dielectric layer from below. For device connection within the cavity, a plurality of electrical contacts are provided at the floor of the cavity.

The leadframe is an integral one-piece textured metal sheet and typically is made of copper. In a preferred embodiment, the leadframe includes a metal frame; metal leads located within and integrated connected to the metal frame; a metal slug located within the metal frame and laterally surrounded by the metal leads; and tie bars connected to the metal slug and the metal frame. As the metal slug can be connected to the metal frame through the tie bars, electrodeposition can be executed on the metal slug by applying voltage on the metal frame.

The metal leads are positioned around the periphery of the cavity and can serve as horizontal and vertical signal transduction pathways or provide ground/power plane for power delivery and return. Each of the metal leads preferably is an integral one-piece lead and has an inner end directed toward the predetermined area for device placement and an outer end situated farther away from the predetermined area than the inner end. In a preferred embodiment, the metal leads are separated from the metal frame and have top and bottom ends and an exterior lateral surface perpendicular to the top and bottom ends and not covered by the resin compound. Typically, the metal leads may have a thickness in a range from about 0.15 mm to about 1.0 mm and laterally extend at least to a perimeter coincident with peripheral edges of the resin compound. Additionally, the metal leads may have stepped peripheral edges interlocked with the resin compound for secure bonds between the metal leads and the resin compound.

The resin compound can provide mechanical bonds between the metal leads, and preferably has a top surface substantially coplanar with the top ends of the metal leads. Based on the topography of the metal leads having stepped peripheral edges, the resin compound can have a stepped cross-sectional profile where it contacts the metal leads so as to prevent the metal leads from being vertically forced apart from the resin compound and also to avoid micro-cracking at the interface along the vertical directions.

The dielectric layer covers the floor of the cavity, and optionally further covers the bottom surface of the resin compound and the bottom ends of the metal leads. Underneath the cavity, the dielectric layer is formed with through openings communicated with the cavity, so that the electrical contacts at the floor of the cavity can be electrically connected to the metal leads by the routing circuitry extending into the through openings. In a preferred embodiment, the dielectric layer is integral with the resin compound and made of the same material as that of the resin compound.

The etching stoppers can be formed by deposition of an etch-resistant material in pits of the metal slug and have a different etch selectivity from the leadframe and the routing circuitry. Under alkaline copper-etching chemistry, the etching stoppers preferably have a higher etch resistance than the routing circuitry and the metal slug so as to protect the routing circuitry from being damaged during the removal of the metal slug. In one embodiment, a metal that has a melting point lower than that of the routing circuitry is included in the etching stoppers. As the metal slug can be connected to the metal frame, it is feasible to electroplate the etching stoppers in the pits of the metal slug by applying voltage on the metal frame. More specifically, the etching stoppers may fill up the pits and extend into through openings located below the pits. As a result, the etching stoppers can have protruded portions located above the floor of the cavity and embedded portions in the dielectric layer. In a preferred embodiment, the protruded portions of the etching stoppers have a thickness of at least about 5 micrometers. As a result, the total thickness of the etching stoppers is at least larger than 5 micrometers. Based on the topography of the pits and the through openings, the protruded portions can have a planar top surface and tapered sidewalls, whereas the embedded portions have a planar bottom surface and tapered sidewalls. More specifically, as the pit diameter decreases from the bottom end of the metal slug to the predetermined depth within the metal slug, the diameter of the protruded portions decrease as it projects from the floor of the cavity. Likewise, due to the increase in the diameter of the through openings from the bottom end of the metal slug to the bottom surface of the dielectric layer, the diameter of the embedded portions increase as it extends from the floor of the cavity into the dielectric layer. Further, as the pits typically laterally extend beyond the periphery of their respective through openings at the bottom end of the metal slug (i.e. the bottom diameter of the pits is larger than the top diameter of the through openings), the bottom diameter of the protruded portions is larger than the top diameter of the embedded portions. Alternatively, the etching stoppers may be electroplated as layer-like etch barriers on the walls of the pits and not extend into the through openings. In this case, the etching stoppers preferably have sufficient thickness of at least about 0.5 micrometer and completely cover pit walls so as to isolate the subsequent routing circuitry from the metal slug and thus to avoid etching of the routing circuitry during removal of the metal slug.

The routing circuitry is spaced from the cavity by the etching stoppers and contacts the etching stoppers and the metal leads to provide electrical connection between the electrical contacts at the floor of the cavity and the metal leads. In a preferred embodiment, the routing circuitry is a patterned metal layer that is deposited on the bottom surface of the dielectric layer and has selected portions extending into the through openings of the resin compound to form conductive vias located below the floor of the cavity and having tapered sidewalls. In one embodiment, the routing circuitry contacts the etching stoppers in the through openings of the dielectric layer, and an interfacial material layer is formed at a level between the floor of the cavity and the bottom surface of the dielectric layer. Alternatively, the routing circuitry may further extend into the pits of the metal slug so as to form protruded bumps located above the floor of the cavity and having a planar top surface and tapered sidewalls. In this alternative aspect, an interfacial material layer is formed at a level above the floor of the cavity. Based on the topography of the pits and the through openings, the bottom diameter of the protruded bumps typically is larger than the top diameter of the conductive vias. More specifically, the diameter of the protruded bumps decrease as it projects from the floor of the cavity, whereas the diameter of the conductive vias increase as it extends from the floor of the cavity into the dielectric layer. When the dielectric layer further covers the bottom ends of the metal leads, the routing circuitry also extends into additional through openings aligned with the metal leads to form conductive vias in contact with the bottom ends of the metal leads.

The connecting circuitry may be a multi-layered build-up circuitry and include at least one insulating layer and at least one routing layer serially formed in an alternate fashion. The routing layer extends through the insulating layer to form metallized vias and extends laterally on the insulating layer. Accordingly, the connecting circuitry can be electrically coupled to the top ends of the metal leads through the metallized vias in the insulating layer. More specifically, the connecting circuitry can be formed on the top surface of the resin compound and the top end of the leadframe before removing the metal slug, and a selected portion of the connecting circuitry corresponding to the metal slug can be removed, followed by removing the metal slug.

The present invention also provides a semiconductor assembly in which a first semiconductor device is disposed in the cavity of the aforementioned interconnect substrate and electrically connected to the etching stoppers. Specifically, the first semiconductor device can be face-down disposed in the cavity and electrically connected to the routing circuitry by conductive bumps mounted on the etching stoppers. Additionally, a second semiconductor device may be further attached on a top surface of the first semiconductor device and electrically coupled to the top ends of the metal leads through second bonding wires.

The assembly can be a first-level or second-level single-chip or multi-chip device. For instance, the assembly can be a first-level package that contains a single chip or multiple chips. Alternatively, the assembly can be a second-level module that contains a single package or multiple packages, and each package can contain a single chip or multiple chips. The first and second semiconductor devices can be packaged or unpackaged chips. For instance, the first and second semiconductor devices can be bare chips, or wafer level packaged dies, etc.

The term “cover” refers to incomplete or complete coverage in a vertical and/or lateral direction. For instance, in a preferred embodiment, the protruded bumps of the routing circuitry are completely covered by the etching stoppers and spaced from the cavity by the etching stoppers.

The phrases “mounted to” and “attached on” include contact and non-contact with a single or multiple support element(s). For instance, in a preferred embodiment, the second semiconductor device can be mounted on the first semiconductor regardless of whether the second semiconductor device is separated from the first semiconductor device by the adhesive.

The phrases “electrically connected” and “electrically coupled” refer to direct and indirect electrical connection. For instance, in a preferred embodiment, the connecting circuitry can be electrically connected to the routing circuitry by the metal leads but does not contact the routing circuitry.

The interconnect substrate and the semiconductor assembly made by this method is reliable, inexpensive and well-suited for high volume manufacture. The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. An interconnect substrate, comprising:
a plurality of metal leads that laterally surround a predetermined area and each have a top end and a bottom end;
a resin compound that fills in spaces between the metal leads and laterally extends into the predetermined area to laterally surround a periphery of cavity at the predetermined area and has a top surface adjacent to an entrance of the cavity;
a dielectric layer that covers a floor of the cavity and has a bottom surface positioned at a level below the floor of the cavity;
a plurality of through openings that are aligned with the cavity and disposed in the dielectric layer;
a routing circuitry that laterally extends on the bottom surface of the dielectric layer and is electrically coupled to the bottom ends of the metal leads and extends into the through openings; and
a plurality of electroplated etching stoppers that project from the floor of the cavity and extend into the through openings and contact the routing circuitry in the through openings of the dielectric layer.

2. The interconnect substrate of claim 1, wherein the electroplated etching stoppers have a thickness of at least 5 micrometers.

3. The interconnect substrate of claim 1, wherein the electroplated etching stoppers comprise a metal that has a melting point lower than that of the routing circuitry.

4. The interconnect substrate of claim 1, wherein the electroplated etching stoppers have a higher etch resistance than the routing circuitry under alkaline copper-etching chemistry.

5. The interconnect substrate of claim 1, wherein the dielectric layer is integral with the resin compound.

6. The interconnect substrate of claim 1, further comprising tie bars placed around the periphery of the cavity.

7. The interconnect substrate of claim 1, wherein the diameter of the through openings decreases as the through openings extend from the bottom surface of the dielectric layer to the floor of the cavity.

8. The interconnect substrate of claim 1, further comprising a connecting circuitry that is disposed over the top surface of the resin compound and electrically coupled to the top ends of the metal leads.

9. An interconnect substrate, comprising:
a plurality of metal leads that laterally surround a predetermined area and each have a top end and a bottom end;
a resin compound that fills in spaces between the metal leads and laterally extends into the predetermined area to laterally surround a periphery of cavity at the predetermined area and has a top surface adjacent to an entrance of the cavity;
a dielectric layer that covers a floor of the cavity and has a bottom surface positioned at a level below the floor of the cavity;
a plurality of through openings that are aligned with the cavity and disposed in the dielectric layer;
a routing circuitry that laterally extends on the bottom surface of the dielectric layer and is electrically coupled to the bottom ends of the metal leads and extends into the through openings and projects from the floor of the cavity to form a plurality of protruded bumps located above the floor of the cavity; and
a plurality of electroplated etching stoppers that contact and cover the protruded bumps of the routing circuitry.

10. The interconnect substrate of claim 9, wherein the electroplated etching stoppers have a thickness of at least 0.5 micrometer.

11. The interconnect substrate of claim 9, wherein the electroplated etching stoppers comprise a metal that has a melting point lower than that of the routing circuitry.

12. The interconnect substrate of claim 9, wherein the electroplated etching stoppers have a higher etch resistance than the routing circuitry under alkaline copper-etching chemistry.

13. The interconnect substrate of claim 9, wherein the dielectric layer is integral with the resin compound.

14. The interconnect substrate of claim 9, further comprising tie bars placed around the periphery of the cavity.

15. The interconnect substrate of claim 9, wherein the diameter of the through openings decreases as the through openings extend from the bottom surface of the dielectric layer to the floor of the cavity.

16. The interconnect substrate of claim 9, further comprising a connecting circuitry that is disposed over the top surface of the resin compound and electrically coupled to the top ends of the metal leads.

17. A semiconductor assembly, comprising:
the interconnect substrate of claim 1; and
a first semiconductor device disposed in the cavity of the interconnect substrate and electrically connected to the electroplated etching stoppers.

18. The semiconductor assembly of claim 17, further comprising a second semiconductor device disposed above the first semiconductor device and electrically connected to the metal leads.
